(19) United States
(12) Patent Application Publication
(10) Pub. No.: US 2006/0196643 A1
(43) Pub. Date: Sep. 7, 2006

(54) Cooling system and electronic apparatus

(76) Inventors: Yukihiko Hata, Hamura-shi (JP); Kentaro Tomioka, Sayama-shi (JP)

Correspondence Address: DLA PIPER RUDNICK GRAY CARY US LLP, P. O. BOX 9271, RESTON, VA, 20195, US

(21) Appl. No.: 11/265,147

(22) Filed: Nov. 3, 2005

(30) Foreign Application Priority Data
Mar. 3, 2005 (JP) 2005-059274

(51) Int. Cl. H05K 7/20

(52) U.S. Cl. 165/104.33; 165/80.4; 361/699

(57) ABSTRACT

A cooling system includes a heat receiving portion thermally connected to a heating element, a heat radiating portion which radiates a heat of the heating element, and a circulation path circulating a liquid coolant between the heat receiving portion and the heat radiating portion. The circulation path includes a reservoir which holds the liquid coolant, wherein the reservoir section includes a third pipe having a first opening end and a second opening end positioned at an opposite side of the first opening end, a first pipe inserted into the first opening end, and a second pipe inserted into the second opening end, and wherein each of the first pipe and the second pipe opens in the third pipe so as to provide gaps respectively, between an inside of the third pipe and an outside of the first pipe and between an inside of the third pipe and an outside of the second pipe.

### CROSS-REFERENCE TO RELATED APPLICATIONS

This application is based upon and claims the benefit of priority from the prior Japanese Patent Application No. 2005-059274, filed Mar. 3, 2005, the entire contents of which are incorporated herein by reference.

### BACKGROUND

1. Field

The embodiments of the invention generally relate to liquid cooling systems and an electronic apparatus, the cooling system circulating a liquid coolant to cool a heat generating element such as a CPU.

2. Description of the Related Art

Microprocessors for use in notebook computers generate more heat while operating, as they process data at higher speeds and perform more functions. Recently, liquid cooling systems have been developed to cool the microprocessors.

U.S. Pub. No. 2005/0007735 discloses a liquid cooling system used in a notebook size portable computer including a body portion and a display portion. The cooling system is provided with a heat receiving portion thermally connected to a heat generating component, such as a CPU and a chip set, a circulation path filled with cooling liquid and a heat radiating portion. The computer includes a body, a display and a support portion connected between the body and the display. The heat receiving portion is provided in the body. The heat radiating portion is provided in the support portion. The circulation path connects between the heat receiving portion and the heat radiating portion.

A reserve tank, provided in the support portion, holds the cooling liquid. The reserve tank supplies cooling liquid to the circulation path. The reserve tank has a large housing to hold the liquid coolant.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing a portable computer according to a first embodiment of the present invention;

FIG. 2 is a side view showing the portable computer of FIG. 1 in a partially fragmental manner;

FIG. 3 is a dissembled perspective view when part of the portable computer of FIG. 1 is seen from its lower wall side;

FIG. 4 is a perspective view when a cooling system according to the first embodiment of the present invention is seen in an opposite side of a heat receiving face side;

FIG. 5 is a plan view when the cooling system of FIG. 2 is seen from the heat receiving face side;

FIG. 6 is a sectional view taken along the line VI-VI shown in FIG. 5;

FIG. 7 is a perspective view showing a heat radiating section of the cooling system of FIG. 2;

FIG. 8 is a sectional view showing the heat radiating section of the cooling system of FIG. 2 in a direction orthogonal to a mount base;

FIG. 9 is a sectional view showing a reservoir section of the cooling system of FIG. 2 taken along an axial direction of a first pipe;

FIG. 10 is a sectional view taken along the line X-X shown in FIG. 9;

FIG. 11 is a sectional view showing the reservoir section in which the cooling system of FIG. 2 is inclined by 90 degrees in the counterclockwise direction with respect to a horizontal face together with a mount base;

FIG. 12 is a sectional view showing the reservoir section in which the cooling system of FIG. 2 is inclined by 45 degrees in the counterclockwise direction with respect to a horizontal face together with a mount base;

FIG. 13 is a sectional view showing a reservoir section of a cooling system according to a second embodiment of the present invention taken along an axial direction of a first pipe; and

FIG. 14 is a sectional view showing a reservoir section of a cooling system according to a third embodiment of the present invention taken along an axial direction of a first pipe.

### DETAILED DESCRIPTION OF SEVERAL EMBODIMENTS

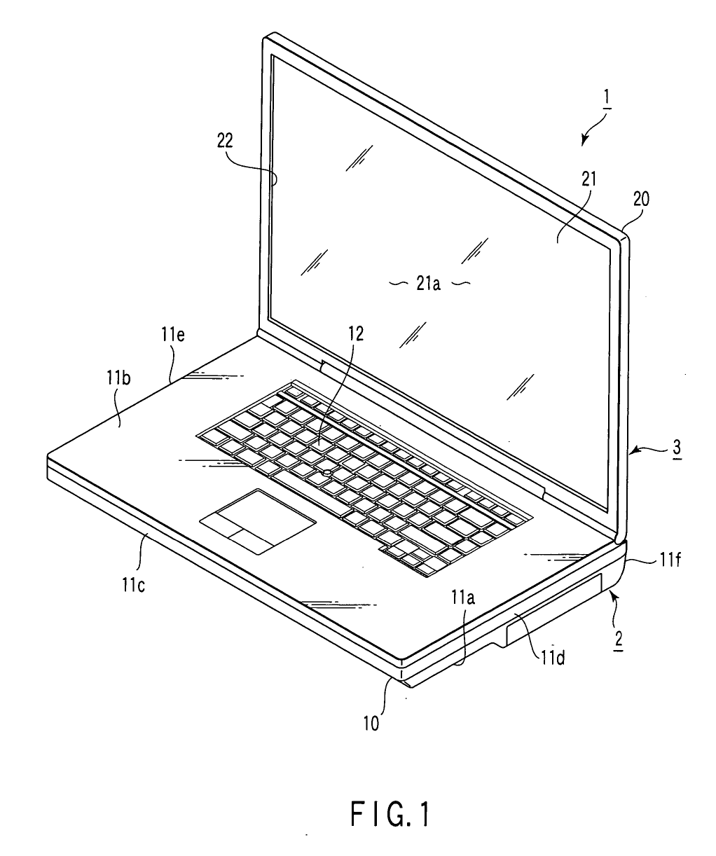

Hereinafter, a first embodiment of the present invention will be described with reference to FIGS. 1 to 12.

FIG. 1 shows a portable computer 1 as an electronic device according to the first embodiment of the present invention. The portable computer 1 has a main unit 2 and a display unit 3.

The main unit 2 has a first housing 10 formed in a flat box shape. The first housing 10 has a bottom wall 11a, an upper wall 11b, a front wall 11c, left and right side walls 11d and 11e, and a rear wall 11f. The upper wall 11b supports a keyboard 12 for inputting a numeral, a character or the like.

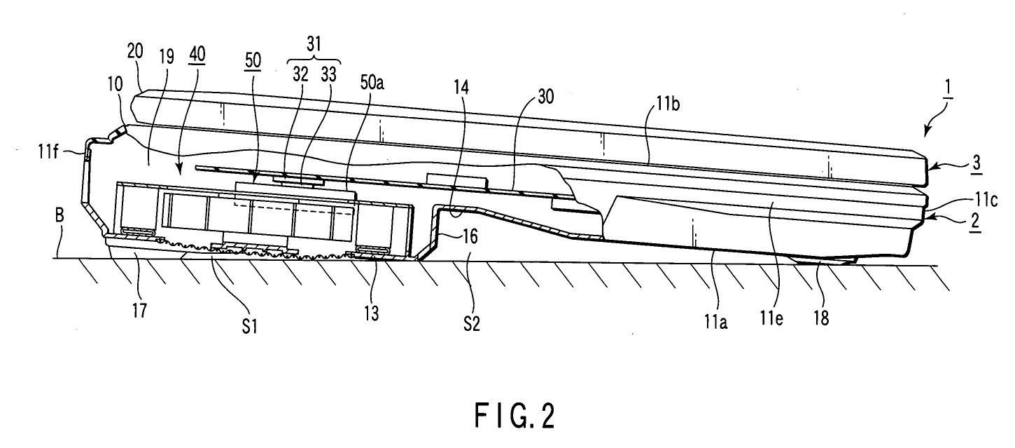

At least a bottom wall 11a of the first housing 10 is made of a metal material such as a magnesium alloy, for example. As shown in FIG. 2, the bottom wall 11a has a expanded section 13 and a recessed section 14. The expanded section 13 is positioned at a latter half section of the bottom wall 11a and protrudes downwardly of a first half section of the bottom wall 11a. The expanded section 13 has a shield wall 16 interposed between the expanded section 13 and the recessed section 14. The recessed section 14 is recessed inwardly of the first housing 10 at a portion immediately in front of the expanded section 13. The recessed section 14 is positioned at a center section taken along a widthwise direction of the first housing 10.

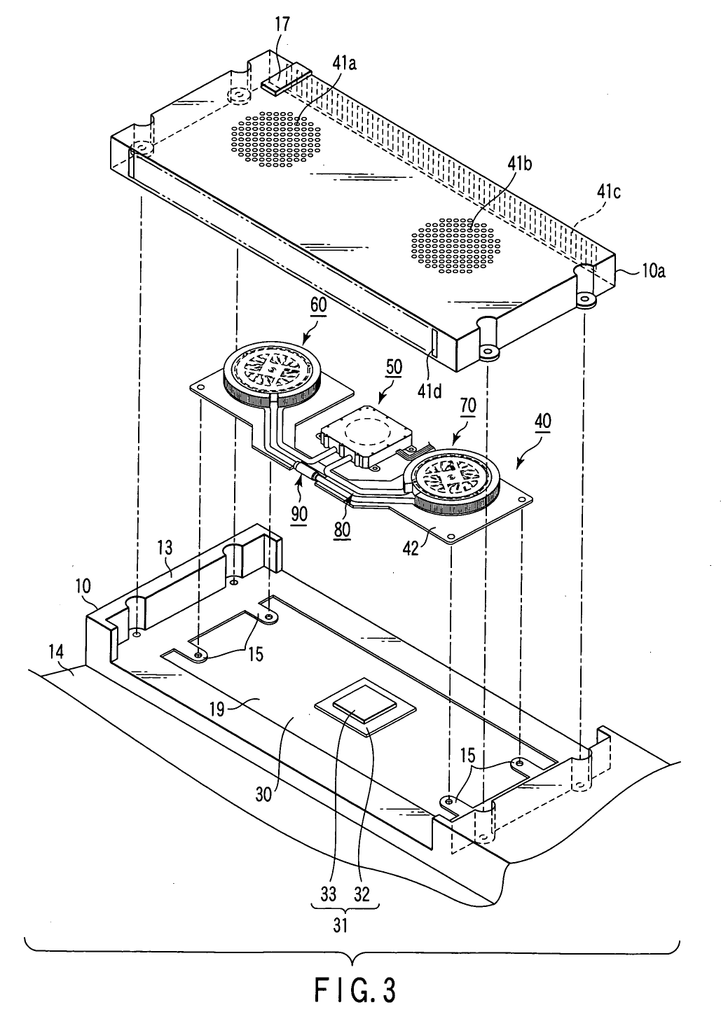

As shown in FIG. 2, a pair of first leg sections 17 (only one of which is shown in FIGS. 2 and 3) are formed at the expanded section 13 of the bottom wall 11a. These first leg sections 17 are distant from each other in the widthwise direction of the first housing 10. A pair of second leg sections 18 (only one of which is shown in FIG. 2) is formed at a front end part of the bottom wall 11a. These second leg sections 18 are distant from each other in the widthwise direction of the first housing 10.

When the portable computer 1 is placed on the top B of a desk, for example, the first and second leg sections 17, 18 come into contact with the top B. As a result, the first housing 10 is inclined in a front downward posture. In addition, a gap S1 is formed between a lower face of the extended section 13 and an upper face of the top B, and a gap S2 is formed between the recessed section 14 and the top B.

As shown in FIG. 1, a display unit 3 includes a second housing 20 and a liquid crystal display panel 21. The liquid crystal display panel 21 is housed in the second housing 20. The liquid crystal display panel 21 has a screen 21a which displays an image. The screen 21a is exposed outwardly of the second housing 20 through an opening 22 formed on a front face of the second housing 20.

The second housing 20 is supported at a rear end part of the first housing 10 via a hinge, not shown. Thus, the display unit 3 can be turned between a closed position at which the display unit lies on the main unit 2 so as to upwardly cover the keyboard 12 and an open position at which the display unit exposes the keyboard 12 or the screen 21a.

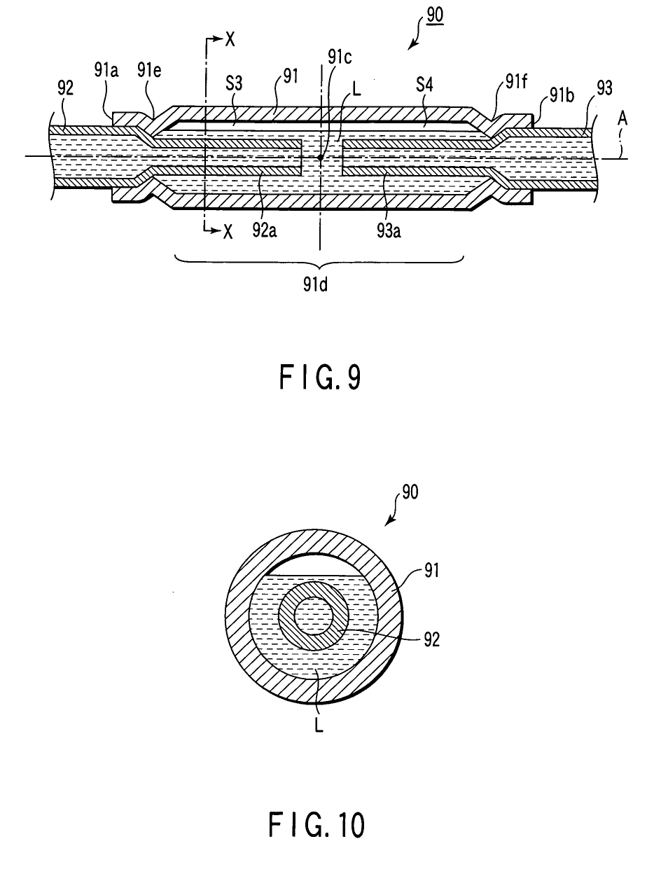

As shown in FIGS. 2 and 3, the first housing 10 houses a printed circuit board 30. A CPU 31 serving as a heat generating element is mounted on a lower face of a rear end part of the printed circuit board 30. The CPU 31 has a base substrate 32 and an IC chip 33 positioned at a center part of the base substrate 32. The IC chip 33 generates a very large amount of heat during high speed processing and when multiple functions are being performed, and requires cooling in order to maintain a stable operation. Therefore, although air cooling can be carried out as a method of cooling the IC chip 33, it is useful to discharge heat via a liquid coolant L (See FIG. 9) having a much higher specific heat than air in order to obtain a high cooling effect.

The portable computer 1 incorporates a liquid cooling system 40 which cools the CPU 31 by using the liquid coolant L such as an unfrozen liquid. As shown in FIGS. 2 and 3, a housing section 19 which houses the cooling system 40 is provided in the first housing 10. In the present embodiment, the housing section 19 is provided inside of the expanded section 13.

In more detail, the first housing 10 has a cover 10a which closes the housing section 19. The cover 10a forms a part of a bottom wall 11a, a part of a rear wall 11f, and a part of a partition wall 16. At the cover 10a, a first exhaust section 41a, a second exhaust section 41b, a third exhaust section 41c, and a fourth exhaust section 41d are provided. A heat radiating section 60 is provided under the first exhaust section 41a. A heat radiating section 70 is provided under the second exhaust section 41b. The first exhaust section 41a and the second exhaust section 41b open toward the gap S1. The third exhaust sections 41c are provided to be arranged in one line in the widthwise direction of the first housing 10 at a portion which serves as the rear wall 11f of the first housing 10. The fourth exhaust section 41d is provided to be arranged in one line in the widthwise direction of the first housing 10 at a portion which serves as the partition wall 16 and opens at the recess section 14. That is, the fourth exhaust section 41d opens toward the gap S2.

As shown in FIGS. 2 to 6, the cooling system 40 includes a pump unit 50 having a heat receiving section (pump housing) 51 thermally connected to the CPU 31, one or more heat radiating sections (for example, two heat radiating sections 60 and 70) which radiate heat from the CPU 31, and a circulation path 80 which circulates the liquid coolant L between the heat receiving section 51 and the heat radiating sections 60 and 70, and a reservoir section 90 which holds the liquid coolant L. Essential portions of the cooling system 40 are mounted on a metallic plate-shaped mount base (support member) 42. FIG. 2 shows the cooling system 40 in which a heat receiving face 51a is set at an upper side (a correct or normal position in which the portable computer 1 is used) and FIGS. 3, 4 and 6 each shows the cooling system 40 upside down. In addition, FIG. 5 shows that the cooling system is seen from the heat receiver face 51a.

The pump unit 50 is provided in the circulation path 80 and pumps the liquid coolant L in the circulation path 80. In the present embodiment, the pump unit 50 both pumps the liquid coolant and functions as a heat receiving section thermally connected to the CPU 31.

In more detail, the pump unit 50 includes a flat box shaped heat receiving section (pump housing) 51, an impeller 52 provided in the heat receiving section (pump housing) 51, and a motor (not shown) which rotates the impeller 52.

The heat receiving section (pump housing) 51 is made of a material having a high heat conductivity such as an aluminum alloy, for example. At least one end face 51a of the heat receiving section (pump housing) 51 is flat, and is thermally connected to the IC chip 33. In addition, the heat receiving section (pump housing) 51 includes a inlet section 53 which suctions the liquid coolant L, and an outlet section 54 which ejects the liquid coolant L.

The motor which rotates the impeller 52, although not shown, is composed of, for example, a ring shaped rotor magnet having a plurality of poles N and a plurality of poles S alternately formed thereon, a stator, and a drive circuit board for operating the motor. The drive circuit board can supply a predetermined drive current to the stator. In this manner, a predetermined magnitude of a current is supplied to the stator at the same time when the portable computer 1 is powered ON, for example. The current is supplied to the stator, whereby a rotating magnetic field is generated in a circumferential direction of the stator, and attraction and repulsion are alternately repeated between a rotor magnet and the stator. A torque taken along the circumferential direction of the rotor magnet is generated between the rotor magnet and the stator, and the impeller 52 is rotated in a predetermined direction.

On the circuit board for drive the motor, a power supply line 55 which supplies a current for operating the motor is provided at a position offset from the inlet section 53 and the outlet section 54. In this manner, the insulation property of the pump unit 50 which circulates the liquid coolant L can be enhanced.

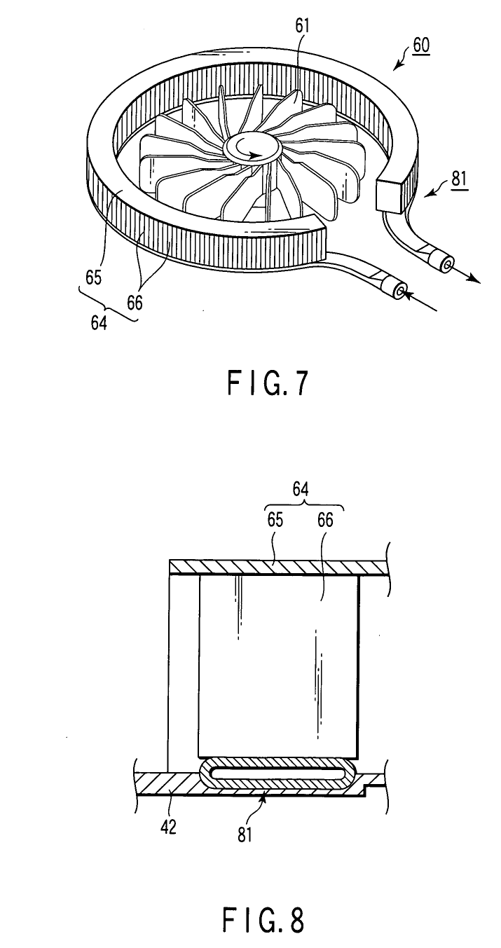

The heat radiating section 60 includes a first cooling fan 61 and a first heat radiating mechanism 64 provided around the first cooling fan 61. The heat radiating section 70 includes a second cooling fan 71 and a second heat radiating mechanism 74 provided around the second cooling fan 71. The heat radiating section 60 and the heat radiation section 70 are mirror images of each other. Thus, FIGS. 7 and 8 each show only the heat radiating section 60, as an example of the heat radiating sections 60 and 70.

The first heat radiating mechanism 64 has a heat radiating element 65 formed in an arc shape or a circular shape of a material having a high thermal conductivity such as copper, aluminum or the like, and a plurality of heat radiating fins (hereinafter, referred to as first heat radiating fins) 66 thermally connected to the heat radiating element 65. Similarly, the second heat radiating mechanism 74 has a heat radiating element 75 formed in an arc shape or a circular shape of a material having a high thermal conductivity such as copper, aluminum or the like, and a plurality of heat radiating fins (hereinafter, referred to as first heat radiating fins) 76 thermally connected to the heat radiating element 75.

The first cooling fan 61 and the second cooling fan 71 are positioned in an approximate center of an arc or circle of the first heat radiating mechanism 64 and the second heat radiating mechanism 74, respectively. The first cooling fan 61 and the second cooling fan 71 are rotated in a predetermined direction by means of a motor which is not described in detail. The circulation path 80 in which the liquid coolant L circulates is provided proximal to or contact with the heat radiating section 60 and the heat radiating section 70 which are rotated.

In the first heat radiating fins 66, a first pipe section 81 connected to the pump unit 50 and having the liquid coolant L circulated therein, is provided to be efficiently thermally conductive. Similarly, in a second heat radiating fins 76, a second pipe section 82 connected to the pump unit 50 and having the liquid coolant L circulated therein, is provided to be efficiently thermally conductive. The first pipe section 81 and second pipe section 82 form part of the circulation path 80 described later in detail.

In a region proximal to or in contact with the heat radiating section 60 or the heat radiating section 70, as shown in FIG. 8 the circulation path 80 (first pipe section 81 and second pipe section 82) is formed in a flat cross section. The circulation path 80 can be thermally coupled to the heat radiating section 60 and the heat radiating section 70, respectively, by means of soldering or molding.

The heat radiating section 60 and the heat radiating section 70 need not be formed in a symmetrical shape (in a mirror image relationship), and may be formed in the same shape. In addition, in the case where the cooling system 40 is provided with a plurality of heat radiating sections, these heat radiating sections can be disposed in an approximately left and right symmetrical manner around the pump unit 50.

Although the pump unit 50 may be offset by a predetermined distance depending on a position of the IC chip 33, at least a part of its external shape can be positioned on line segment N connecting centers of the first and second cooling fans 61 and 71 in a state in which the pump unit is seen from a plan view, as shown in FIG. 5.

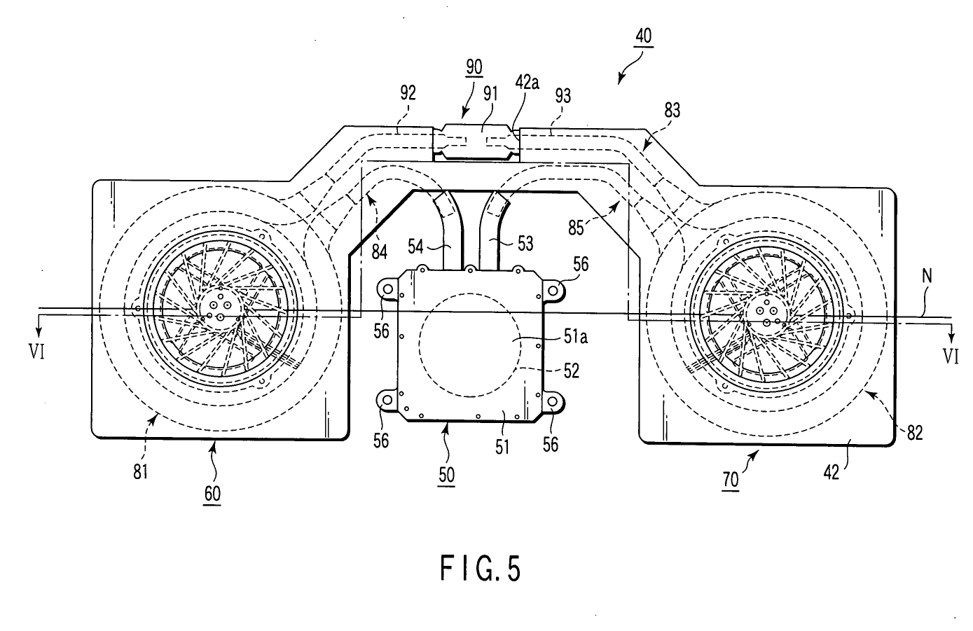

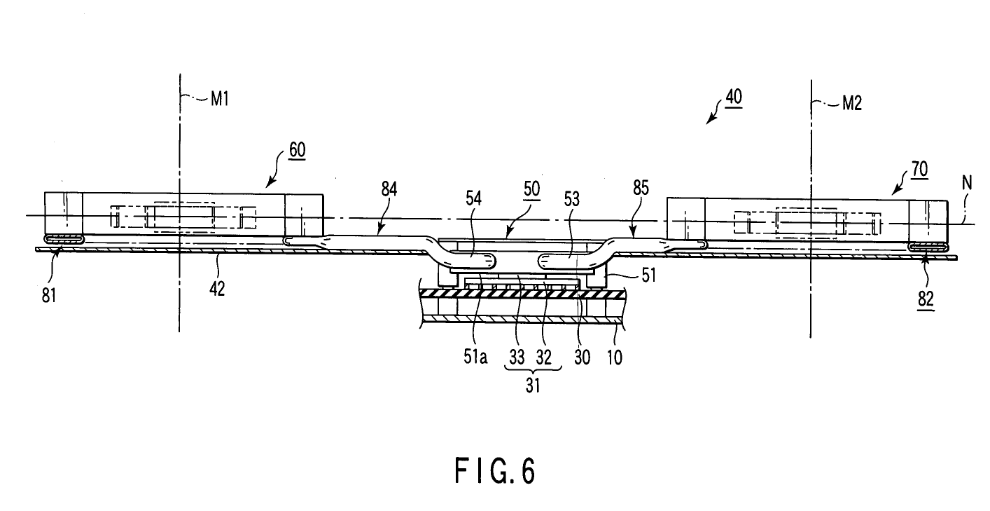

In addition, as shown in FIG. 6, the pump unit 50 may be offset by a predetermined distance in parallel to a virtual plane parallel to the mount base 42 and including line segment N. In the figure, reference numeral M1 denotes a rotary shaft of the first cooling fan 61 and reference numeral M2 denotes a rotary shaft of the second cooling fan 72. Further, the pump unit 50 may be provided in the other face opposite to that of the heat radiating sections 60, 70 positioned on one face of the mount base 42.

The circulation path 80 has an outlet pipe section 84 which connects the outlet section 54 and the first heat radiating fins 66 of the pump unit 50 to each other, the first pipe section 81 thermally connected to the first heat radiating fins 66, the second pipe section 82 thermally connected to the second heat radiating fins 76, a third pipe section 83 which connects the first pipe section 81 and the second pipe section 82, and an inlet pipe section 85 which connects the second heat radiating fins 76 and the inlet section 53 of the pump unit 50 to each other.

In addition, the cooling system 40 includes the reservoir section 90 which holds the liquid coolant L in the circulation path 80, for example, in a third pipe section 8.3, in order to properly maintain the cooling efficiency of the CPU 31 even if the liquid coolant L gradually evaporates. The reservoir section 90 forms part of the circulation path 80. The reservoir section 90 may be provided anywhere in the circulation path 80.

As the circulation path 80, for example, there can be used a pipe or a tube having excellent heat conductivity, cross-section shape of the pipe or tube being made of, for example, copper, brass, or stainless steel, the pipe or pipe being formed cylindrical or non-cylindrical. The circulation path 80 may be, of course, a tube having flexibility such as a rubber. Water or the like as well as unfrozen liquid may be used as the liquid coolant 80.

In the cooling system 40 according to the present embodiment, the outlet pipe section 54 and inlet pipe section 53, which are separated from the mount base 42, are flexible pipes which can be deformed in an arbitrary shape. Such pipes may be made of rubber-based material. In this manner, the degree of freedom for positioning the pump unit 50 is higher than the degree of freedom for positioning the two cooling fans. Therefore, it becomes possible to easily fix the pump unit 50 at a predetermined position according to a position of a heating element (CPU 31). In addition, the inlet pipe section 85 and outlet pipe section 84 can be deformed, thereby making it possible to improve workability when the CPU 31 and the pump 50 are connected to or disconnected from each other.

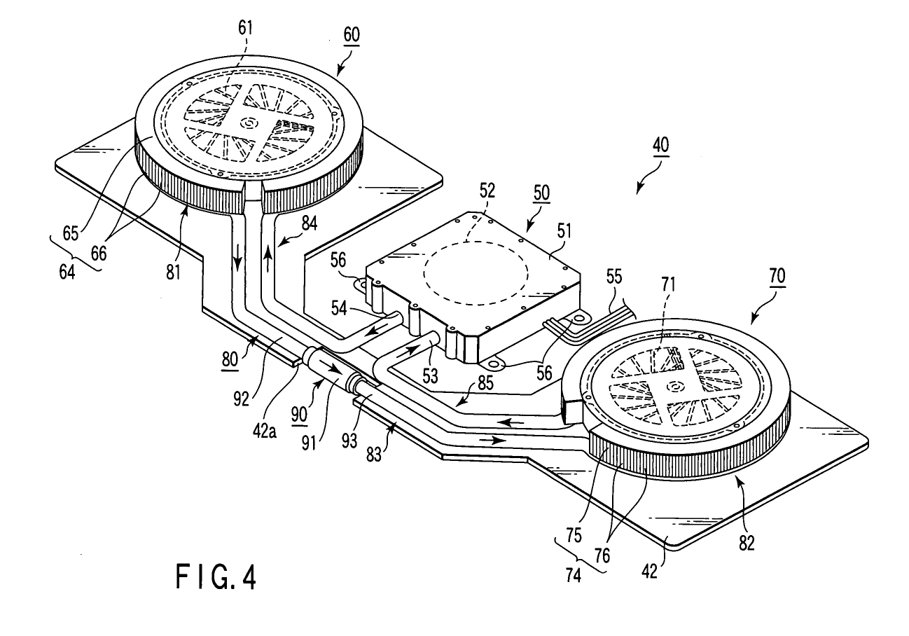

The first heat radiating fins 66, the second heat radiating fins 76, and the second and third sections 82 and 83 are supported by the mount base 42 by means of soldering or molding, for example. The reservoir section 90 is formed so that an outer diameter of the third pipe 91 which holds the liquid coolant L, as described later, is larger than that of each of the second and third pipes 92 and 93. Thus, as shown in FIGS. 3 and 4, a cutout 42a is provided at a portion of the mounting case 42 which corresponds to the third pipe 91.

Between the first heat radiating fins 66 and the mount base 42, between the second heat radiating fins 76 and the mount base 42, and between the circulation path 80 and the mount base 42, a material for thermally enhancing connection efficiency of these elements such as silicone grease or the like may, of course, be provided as required. If the circulation path 80 is a flexible pipe, such as a rubber pipe, it can be mounted by a mount bracket or the like.

The reservoir section 90 will now be described in detail with reference to FIGS. 9 to 12. In the cooling system 40 according to the present embodiment, the third pipe section 83 of the circulation path 80 includes the reservoir section 90. As shown in FIGS. 9 and 10, the reservoir section 90 (third pipe section 83) has a first pipe 92, a second pipe 93, and a third pipe 91 which are externally and internally formed in a circular shape (in a sectional circular shape). The external dimensions and outer diameter of each of the third pipe 91, the first pipe 92, and the second pipe 93 are arbitrary without being limited to the circular shape.

The third pipe 91 has a first opening end 91a and a second opening end 91b positioned at the opposite side of the first opening end 91a. The first pipe 92 is inserted into the first opening end 91a. The second pipe 93 is inserted into the second opening end 91b. An end portion (first end portion) 92a of the first pipe 92 and an end portion (second end portion) 93a of the second pipe 93 are provided symmetrically with respect to a center portion 91c along the direction indicating by the axis A of the third pipe 91. The first pipe 92 and the second pipe 93 open in the third pipe 91, respectively, at the intermediate portion 91d (substantial center portion 91c in the present embodiment) taken along the direction indicated by the axis A of the third pipe 91.

The first pipe 92 is formed integrally with the first pipe section 81. The second pipe 93 is formed integrally with the second pipe section 82. The first pipe 92 may be formed independently of the first pipe section 81. Similarly, the second pipe 93 may be formed independently of the second pipe section 82.

The first pipe 92 and the second pipe 93 are formed, respectively, so that the end portion 92a and the end portion 93a inserted into the third pipe 91 are smaller in outer diameter than a portion extending from the third pipe 91. The outer diameter and the inner diameter of the intermediate portion 91d of the third pipe 91 are set so as to be larger than the outer diameter and the inner diameter of each of the end portions 92a, 93a of the second and third pipes 92, 93. Therefore, gaps S3, S4 are formed, respectively, between an inner surface of the third pipe 91 and an outer surface of the first pipe 92 and between an inner surface of the third pipe 91 and an outer surface of the second pipe 93. The end portion 92a of the first pipe 92 is separated from and opposed to the end portion 93a of the second pipe 93.

In addition, the third pipe 91 has aperture sections 91e, 91f which are reduced in diameter at both ends thereof, so as to come into contact with the outer periphery faces of the second and third pipes 92, 93, respectively. This can be achieved by inserting the first pipe 92 and the second pipe 93 into third pipe 91 and applying a drawing compound process to both ends of the third pipe 91. A portion between the inner face of the third pipe 91 (inner face of the aperture section 91e) and the outer periphery face of the first pipe 92 and a portion between the inner face of the third pipe 91 (inner face of the aperture section 91f) and the outer periphery face of the second pipe 93 are adhesively bonded with each other by means of brazing, respectively, to prevent leakage.

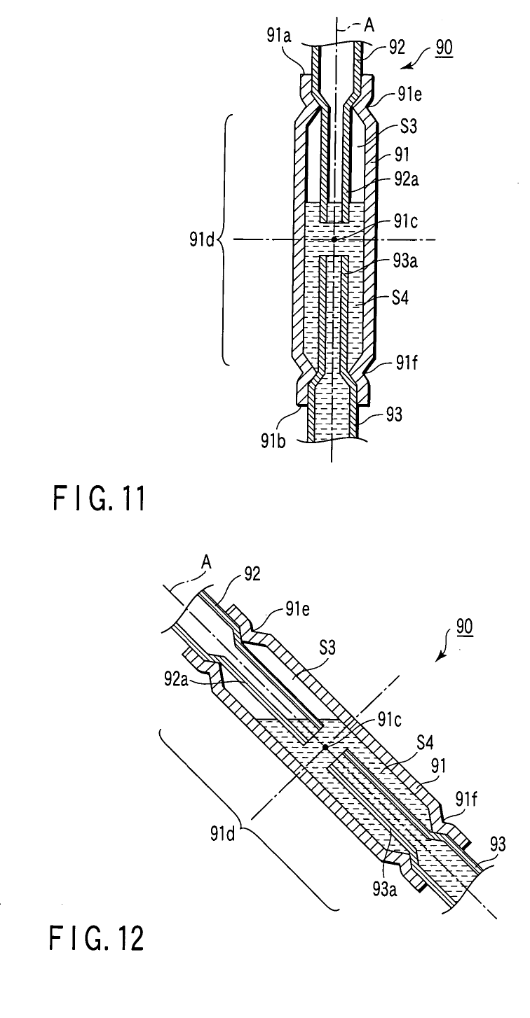

In the reservoir section 90 formed as shown in FIGS. 11 and 12, a portion between the first pipe 92 and the second pipe 93 can be always immersed in the liquid coolant 80 at any angle formed between the cooling system 40 and the horizontal (an angle formed between the mount base 42 and the horizontal). Therefore, air can be restricted from entering from a portion between the first pipe 92 and the second pipe 93 into the circulation path 80. In addition, while the liquid coolant circulates in the circulation path 80, even if air enters the coolant, the air and liquid can be separated from each other between the first pipe 92 and the second pipe 93.

The cooling system 40 is mounted on the first housing 10 as follows (refer to FIG. 2).

The cooling system 40 is housed in the housing section 19, and the pump unit 50 is tightened with screws in the first housing 10 together with the printed circuit board 30. In more detail, extended sections 56 having screw holes are provided at four corners of the heat receiving section (pump housing) 51. Screws passing through extended sections 56 are connected to printed circuit board 30. Screw fastening sections 15 are formed in the first housing 10 at a position which corresponds to corners of mounting base 42. The pump unit 50 is disposed on the printed circuit board 30 so as to fully cover the flat section of the IC chip 33 of the CPU 31. In this manner, the pump unit 50 and the printed circuit board 30 are fixed at their predetermined positions of the first housing 10 and one end face (heat receiving face) 51a of the heat receiving section (pump housing) 51 is thermally connected to the IC chip 33 of the CPU 31 in a reliable heat conductive manner.

The mount base 42 is tightened with screws in the first housing 10 together with the printed circuit board 30. Then, a cover 10a forming part of the first housing 10 is tightened with screws in a main portion of the first housing 10. As described above, the cooling system 40 can be mounted in the first housing 10. Mounting base 42 can provide rigidity and strength to the first housing 10.

The cooling system 40 cools the IC chip 33 of the CPU 31, as described below. Heat radiated from the IC chip 33 is transmitted to the heat receiving section (pump housing) 51 via the heat receiving face 51a. The heat transmitted to the pump housing 51 is transferred to the liquid coolant L in the heat receiving section (pump housing) 51. The liquid coolant L is circulated in the circulation path 80 by pump 50 when power is supplied to the portable computer 1. The liquid coolant L transmitted to the heat radiating section 60 via the ejection pipe section 84 is cooled by the cooling air from the first cooling fan 61 in the vicinity of the first heat radiating fins 66 while the coolant passes through first pipe dust section 81.

The liquid coolant L-having passed through the first pipe section 81 is guided to the third pipe section 83. The third pipe section 83 includes the second and third pipes 92, 93 of the reservoir section 90, which open in the third pipe 91. Thus, even if gas enters the liquid coolant L, air and liquid are separated from each other between the first pipe 92 and the second pipe 93.

The liquid coolant L having passed through the third dust section 83 is cooled by the cooling air from the second cooling fan 71 in the vicinity of the second heat radiating fins 76 while the coolant passes through the second pipe section 82. The liquid coolant L is then introduced into the heat receiving section (pump housing) 51 of the pump unit 50 via the inlet pipe 85. Here, the liquid coolant L is pressurized again, and is fed out to the circulation path 80.

In the meantime, the first exhaust section 41a and the second exhaust section 41b open in the gap S1. The third exhaust section 41c opens rearwardly of the first housing 10. The fourth exhaust section 41d opens in the gap S2. Therefore, the air produced by the first cooling fan 61 and the second cooling fan 71 takes away a heat from the first heat radiating fins 66 and the second heat radiating fins 76, and lowers the temperature of the coolant which flows through the circulation path 80. Thus, the air flows into the first housing 10 via the first exhaust section 41 a and the second exhaust section 41b, and flows outwardly via the third exhaust section 41c and the fourth exhaust section 41d.

In this manner, the heat from the IC chip 33 which is received by the heat receiving face 51a of the pump unit 50 is discharged by the first cooling fan 61 and the second cooling fan 71 provided with the first heat radiating fins 66 and the second heat radiating fins 76. Therefore, a temperature of the IC chip 33 is maintained in an allowable predetermined temperature range. The circulation path 80 is thermally connected to the metallic mount base 42 having a heat radiation effect so that a temperature of the liquid coolant L flowing through the circulation path 80 is lowered (cooled) at a predetermined rate while the coolant is circulated through the circulation path 80.

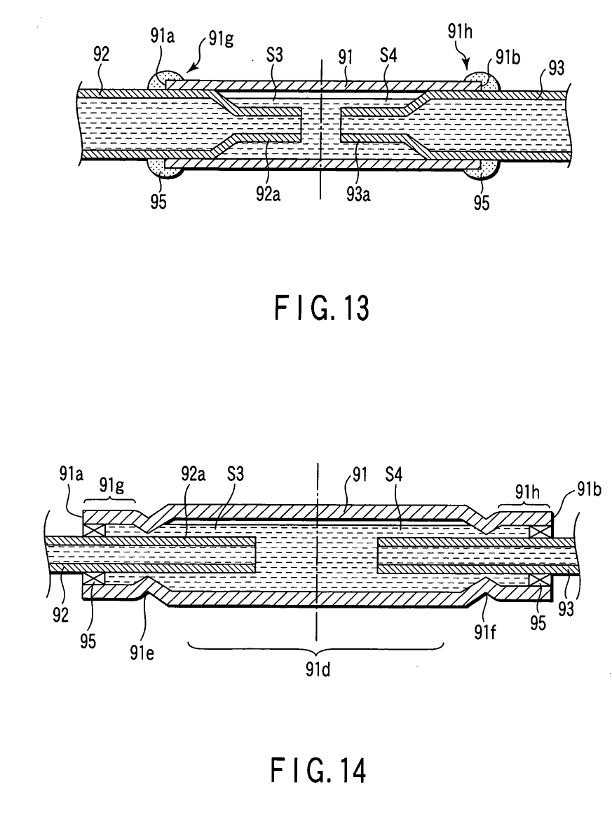

Hereinafter, a second embodiment of the present invention will be described with reference to FIG. 13.

In the second embodiment, a straight pipe is used as the third pipe 91 without bending. In addition, a portion between the third pipe 91 and the first pipe 92 is sealed by brazing a portion between an end portion at the first opening end 91a of the third pipe 91 and the outer face of the first pipe 92. Similarly, a portion between the third pipe 91 and the second pipe 93 is sealed by brazing a portion between an end portion at the first opening end 91 a of the third pipe 91 and the outer face of the second pipe 93. In the figure, reference numeral 95 denotes a brazed portion. Other constituent elements are identical to those of the above-described first embodiment including portions which are not shown. Like elements are designated by like reference numerals. A duplicate description is omitted here.

Now, a third embodiment of the present invention will be described below with reference to FIG. 14.

In the third embodiment, straight pipes are used as the first pipe 92 and the second pipe 93 without bending. In addition, a portion between the third pipe 91 and the first pipe 92 is sealed by brazing a portion between the inner face at the first opening end 91 a of the third pipe 91 and the outer face of the first pipe 92. Similarly, a portion between the third pipe 91 and the third 93 is sealed by brazing a portion between the inner face at the first opening end 91b of the third pipe 91 and the outer face of the second pipe 93. In the figure, reference numeral 95 denotes the brazed portion. Other constituent elements are identical to those of the above-described first embodiment including portions which are not shown. Like elements are designated by like reference numerals. A duplicate description is not written here.

The present invention is not limited to the above-described first to third embodiments. Various modifications can occur without departing from the spirit of the invention. For example, in the first to third embodiments, although two heat radiating sections are provided at both sides of a pump unit, the number of heat radiating sections is arbitrary. In the case where three heat radiating sections are provided, the third radiating section may be provided integrally with the pump unit, for example.

A circulation path bought into contact with or proximate to heat radiating fins may be provided at the inner diameter side or at the outer diameter side of the heat radiating fins. The circulation path may be disposed so as to circulate two or more turns around the heat radiating fins. Any heat generating element may be provided without being limited to a CPU.

What is claimed is:

1. An electronic apparatus, comprising:
a heat generating component;
a heat receiving portion thermally connected to the heat generating component;
a heat radiating portion radiating the heat received by the heat receiving portion; and
a circulating path circulating liquid coolant between the heat receiving portion and the heat-radiating portion;
the circulating path including:
a first pipe having a first end portion;
a second pipe having a second end portion opposing the first end portion of the first pipe and separated from the first end portion of the first pipe; and
a third pipe having a third end portion connecting to the first pipe and a fourth end portion connecting to the second pipe, including gaps provided between an inner surface of the third pipe and an outer surface of the first pipe and between the inner surface of the third pipe and an outer surface of the second pipe.

2. The electronic apparatus according to claim 1, wherein the first end portion of the first pipe and the second end portion of the second pipe are provided symmetrically with respect to a center portion taken along an axial direction of the third pipe.

3. The electronic apparatus according to claim 1, wherein a portion between the inner surface of the third pipe and the outer surface of the second pipe and a portion between the inner surface of the third pipe and the outer surface of the first pipe each are sealed by brazing.

4. The electronic apparatus according to claim 1, wherein the heat receiving portion includes a pump, the pump circulating the liquid coolant in the circulation path.

5. The electronic apparatus according to claim 1, wherein the first pipe, the second pipe and the third pipe are metal.

6. A cooling system comprising:
a heat receiving portion thermally connected to a heat generating component;
a heat radiating portion radiating the heat received by the heat receiving portion; and
a circulating path circulating liquid coolant between the heat receiving portion and the heat-radiating portion;
the circulating path including:
a first pipe having a first end portion;
a second pipe having a second end portion opposing to the first end portion of the first pipe and separated from the first end portion of the first pipe; and
a third pipe having a third end portion connecting to the first pipe and a fourth end portion connecting to the second pipe, including gaps provided between an inner surface of the third pipe and an outer surface of the first pipe and between the inner surface of the third pipe and an outer surface of the second pipe.

7. The cooling system according to claim 6, wherein the first end portion of the first pipe and the second end portion of the second pipe are provided symmetrically with respect to a center portion taken along an axial direction of the third pipe.

8. The cooling system according to claim 6, wherein a portion between the inner surface of the third pipe and the outer surface of the second pipe and a portion between the inner surface of the third pipe and the outer surface of the first pipe each are sealed by brazing.

9. The cooling system according to claim 6, wherein the heat receiving portion includes a pump, the pump circulating the liquid coolant in the circulation path.

10. The cooling system according to claim 6, wherein the first pipe, the second pipe and the third pipe are made of metal.
